(19) United States
(12) Patent Application Publication
(10) Pub. No.: US 2016/0099678 A1
(43) Pub. Date: Apr. 7, 2016

(54) VCO, PLL, AND VARACTOR CALIBRATION

(71) Applicant: QUALCOMM Incorporated, San Diego, CA (US)

(72) Inventors: Xiaohua KONG, San Diego, CA (US); Deqiang SONG, San Diego, CA (US); Zhi ZHU, San Diego, CA (US); Cheng ZHONG, San Diego, CA (US)

(21) Appl. No.: 14/507,775

(22) Filed: Oct. 6, 2014

(51) Int. Cl. H03B 5/12; H03L 7/099

(52) U.S. Cl. CPC H03B 5/124; H03B 5/1212; H03L 7/099

(57) ABSTRACT

In one aspect, a VCO is provided. The VCO includes an inductor, a voltage-controlled capacitive element configured to operate with the inductor to generate an oscillating signal, a voltage supply configured to provide a plurality of voltages to the voltage-controlled capacitive element in a calibration mode, and a control circuit configured to store frequency information indicating frequencies of the oscillating signal in response to the plurality of voltages being provided to the voltage-controlled capacitive element. In another aspect, a PLL is provided. The PLL includes means for selecting, in an open loop configuration, a capacitance of a capacitor based on a target frequency and means for selecting, in a closed loop configuration, an operation voltage of a voltage-controlled capacitive element based on the capacitance of the capacitor.

### BACKGROUND

1. Field

The present disclosure relates generally to electronic circuits, and more particularly, to methods and apparatuses for calibrating voltage-controlled capacitive elements, voltage-controlled oscillators, and phase-locked loops.

2. Background

A wireless device (e.g., a cellular phone or a smartphone) may transmit and receive data for two-way communication with a wireless communication system. The wireless device may include a transmitter for data transmission and a receiver for data reception. For data transmission, the transmitter may modulate a local oscillator (LO) signal with data to obtain a modulated radio frequency (RF) signal, amplify the modulated RF signal to obtain an output RF signal having the desired output power level, and transmit the output RF signal via an antenna to a remote device. For data reception, the receiver may obtain a received RF signal via the antenna, amplify and downconvert the received RF signal with an LO signal, and process the downconverted signal to recover data sent by the remote device.

Voltage-controlled oscillators (VCOs) are often used to generate the LO signals. A VCO is an oscillator whose frequency is controlled by a voltage input. A type of the VCO utilizes a voltage-controlled capacitive element (such as a varactor) in an inductor-capacitor (LC) tank to tune and generate a target oscillating frequency. A phase-locked loop (PLL) may incorporate the VCO and adjusts the input voltage of the VCO to tune the transmitter or receiver. The PLL is generally implemented with a phase detector that compares the phase of the VCO output with the phase of a reference signal and adjusts the voltage input to the VCO to keep the phases aligned. The ability of the PLL to accurately maintain the phase alignment between the reference signals depends on the VCO generating accurate oscillating frequencies. A common challenge among skilled artisans in designing a wireless device transmitters and receivers is to achieve the accurate VCO oscillating frequencies.

Another application of a PLL incorporating a VCO is in a serializer/deserializer or SerDes interface. In one example, a SerDes transmitter converts parallel data into a bitstream, and each such bitstream is transmitted serially via a pair of differential transmission lines to a SerDes receiver. The parallel-to-serial conversion and the transmission of the bitstream may be synchronized with a bit-rate clock generated by a PLL (incorporating a VCO) based on a reference clock. The reference clock is likewise provided to the SerDes receiver. The SerDes receiver may utilize a PLL to generate a recover clock (which may have a same frequency as the bit-rate clock) from the received reference clock, and clock the input bitsteam or bitstreams using the recover clock.

### SUMMARY

Aspects of a VCO apparatus are provided. The apparatus includes an inductor, a voltage-controlled capacitive element configured to operate with the inductor to generate an oscillating signal, a voltage supply configured to provide a plurality of voltages to the voltage-controlled capacitive element in a calibration mode, and a control circuit configured to store frequency information indicating frequencies of the oscillating signal in response to the plurality of voltages being provided to the voltage-controlled capacitive element.

Aspects of a PLL apparatus are provided. The PLL apparatus includes means for selecting, in an open loop configuration, a capacitance of a capacitor based on a target frequency and means for selecting, in a closed loop configuration, an operation voltage of a voltage-controlled capacitive element based on the capacitance of the capacitor.

Aspects of a method for operating a VCO are provided. The method includes providing a plurality of voltages from a first source to a voltage-controlled capacitive element, storing frequency information indicating frequencies of an output signal generated in response to the plurality of voltages, selecting an operation voltage for the voltage-controlled capacitive element based on the stored frequency information of the output signal, and providing the operation voltage from a second source to the voltage-controlled capacitive element.

Aspects of a method for operating a PLL are provided. The method includes selecting, in an open loop configuration, a capacitance of a capacitor based on a target frequency and selecting, in a closed loop configuration, an operation voltage of a voltage-controlled capacitive element based on the capacitance of the capacitor.

It is understood that other aspects of apparatus, circuits and methods will become readily apparent to those skilled in the art from the following detailed description, wherein various aspects of apparatus, circuits and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of apparatus, circuits and methods will now be presented in the detailed description by way of example, and not by way of limitation, with reference to the accompanying drawings, wherein:

FIG. 1A is a function block diagram illustrating an exemplary embodiment of a SerDes interface using PLLs.

FIG. 1B is a conceptual block diagram illustrating an exemplary embodiment of a wireless device.

FIG. 2 is a block diagram illustrating an exemplary embodiment of a wireless transceiver.

FIG. 3 is a block diagram illustrating an exemplary embodiment of a PLL including a VCO.

FIG. 4 is a block diagram illustrating an exemplary embodiment of a VCO including a voltage-controlled capacitive element.

FIG. 5 is a graph illustrating the oscillating frequency of a VCO in response to the operational frequency and the control voltage.

FIG. 6 is a block diagram illustrating an exemplary embodiment of a VCO with varactor calibration.

FIG. 7 is a flow chart for calibrating a PLL and a VCO.

FIG. 8 is a functional block diagram illustrating an exemplary embodiment of control circuits of a PLL and a VCO with varactor calibration.

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific details for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention. Acronyms and other descriptive terminology may be used merely for convenience and clarity and are not intended to limit the scope of the invention.

The word “exemplary” is used herein to mean serving as an example, instance, or illustration. Any embodiment described herein as “exemplary” is not necessarily to be construed as preferred or advantageous over other embodiments. Likewise, the term “embodiment” of an apparatus, circuit or method does not require that all embodiments of the invention include the described components, structure, features, functionality, processes, advantages, benefits, or modes of operation.

The terms “connected,” “coupled,” or any variant thereof, mean any connection or coupling, either direct or indirect, between two or more elements, and can encompass the presence of one or more intermediate elements between two elements that are “connected” or “coupled” together. The coupling or connection between the elements can be physical, logical, or a combination thereof. As used herein, two elements can be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Any reference to an element herein using a designation such as “first,” “second,” and so forth does not generally limit the quantity or order of those elements. Rather, these designations are used herein as a convenient method of distinguishing between two or more elements or instances of an element. Thus, a reference to first and second elements does not mean that only two elements can be employed, or that the first element must precede the second element.

As used herein, the terms “comprises”, “comprising,”, “includes” and/or “including”, when used herein, specify the presence of the stated features, integers, steps, operations, elements, and/or components, but do not preclude the presence or addition of one or more other features, integers, steps, operations, elements, components, and/or groups thereof.

Various aspects of PLLs and VCOs for, e.g., tuning the frequency of transmitters and receivers in wireless devices or a SerDes interface will now be presented. However, as those skilled in the art will readily appreciate, such aspects may be extended to other circuit configurations and devices. By way of example, various aspects of the present invention may be used for signal recovery in a noisy channel, frequency synthesis, clock distribution, and other suitable uses that require PLL, VCO, or similar circuit. Accordingly, all references to a specific application for a PLL or a VCO, or any component, structure, feature, functionality, or process within a PLL are intended only to illustrate exemplary aspects of a PLL with the understanding that such aspects may have a wide differential of applications.

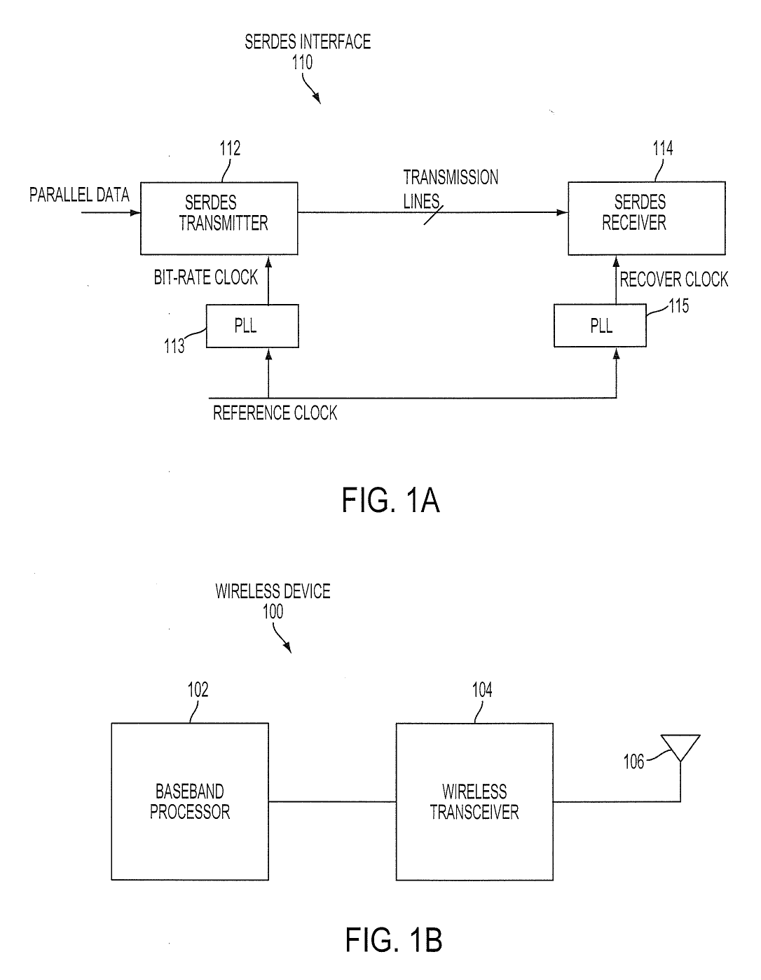

Various embodiments of PLLs may be used in SerDes interfaces of an electronic device. FIG. 1A is a function block diagram illustrating an exemplary embodiment of a SerDes interface using PLLs. The SerDes interface 110 includes a SerDes transmitter 112 and a SerDes receiver 114. The SerDes transmitter 112 receives parallel data and converts that data to a bitstream. The bitstream is transmitted serially via the transmission lines to the SerDes receiver 114. The parallel-to-serial conversion and the serial transmission are based on the bit-rate clock. The bit-rate clock is generated by the PLL 113 based on a reference clock. The SerDes receiver 114 receives the bitstream and recovers the serially transmitted data using a recover clock. The recover clock may be a same frequency as the bit-rate clock. The PLL 115 generates the recover clock based on the reference clock.

Various embodiments of a PLL may be used in a wireless device, such as a mobile phone, personal digital assistant (PDA), desktop computer, laptop computer, palm-sized computer, tablet computer, set-top box, navigation device, work station, game console, media player, or any other suitable device. FIG. 1B is a conceptual block diagram illustrating an exemplary embodiment of such a wireless device. The wireless device 100 may be configured to support any suitable multiple access technology, including by way of example, Code Division Multiple Access (CDMA) systems, Multiple-Carrier CDMA (MCCDMA), Wideband CDMA (W-CDMA), High-Speed Packet Access (HSPA, HSPA+) systems, Time Division Multiple Access (TDMA) systems, Frequency Division Multiple Access (FDMA) systems, Single-Carrier FDMA (SC-FDMA) systems, Orthogonal Frequency Division Multiple Access (OFDMA) systems, or other multiple access technologies. The wireless device 100 may be further configured to support any suitable air interface standard, including by way of example, Long Term Evolution (LTE), Evolution-Data Optimized (EV-DO), Ultra Mobile Broadband (UMB), Universal Terrestrial Radio Access (UTRA), Global System for Mobile Communications (GSM), Evolved UTRA (E-UTRA), IEEE 802.11 (Wi-Fi), IEEE 802.16 (WiMAX), IEEE 802.20, Flash-OFDM, Bluetooth, or any other suitable air interface standard. The actual air interface standard and the multiple access technology supported by the wireless device 100 will depend on the specific application and the overall design constraints imposed on the system.

The wireless device 100 includes a baseband processor 102, a wireless transceiver 104, and an antenna 106. The wireless transceiver 104 may employ various aspects of phase-locked loops presented throughout this disclosure to generate one or more LO signals to support both a transmitting and receiving function. The wireless transceiver 104 performs the transmitting function by modulating one or more carrier signals with a data generated by the baseband processor 102 for transmission over a wireless channel through the antenna 106. The wireless transceiver 104 performs a receiving function by demodulating one or more carrier signals received from the wireless channel through the antenna 106 to recover data for further processing by the baseband processor 102. The baseband processor 102 provides the basic protocol stack required to support wireless communications, including for example, a physical layer for transmitting and receiving data in accordance with the physical and electrical interface to the wireless channel, a data link layer for managing access to the wireless channel, a network layer for managing source to destination data transfer, a transport layer for managing transparent transfer of data between end users, and any other layers necessary or desirable for establishing or supporting a connection to a network through the wireless channel.

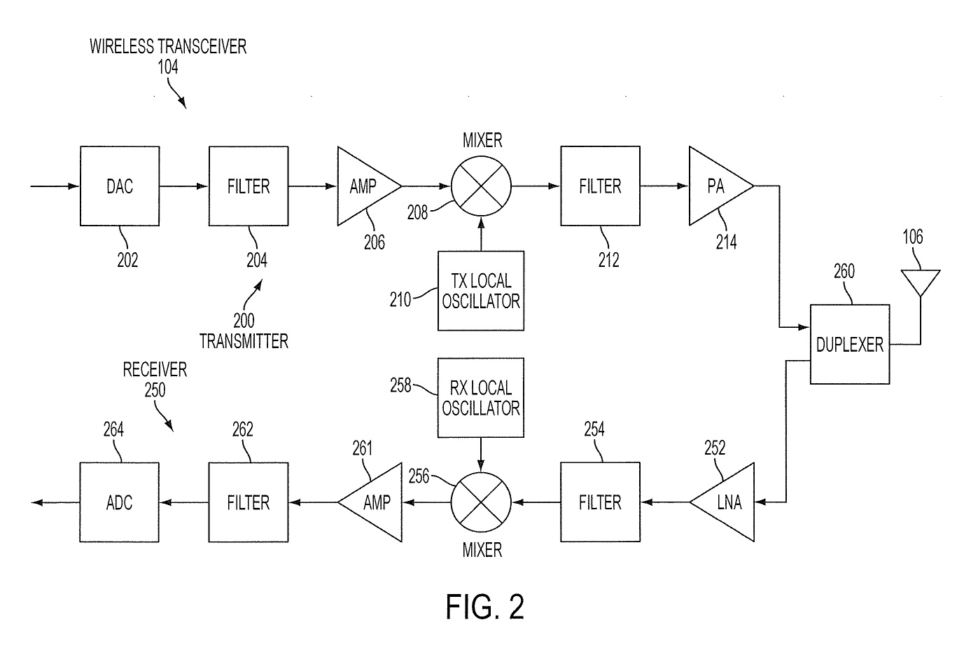

FIG. 2 is a block diagram of an exemplary embodiment of a wireless transceiver. The wireless transceiver 104 includes a transmitter 200 and a receiver 250 that support bi-directional communication. The transmitter 200 and/or the receiver 250 may be implemented with a super-heterodyne architecture or direct-conversion architecture. In the super-heterodyne architecture, a signal is frequency converted between RF and baseband in multiple stages (e.g., from RF to an intermediate frequency (IF) in one stage, and then from IF to baseband in another stage for a receiver). In the direct-conversion architecture, which is also referred to as a zero-IF architecture, a signal is frequency converted between RF and baseband in one stage. The super-heterodyne and direct-conversion architectures may use different circuit blocks and/or have different requirements. In the exemplary embodiment shown in FIG. 2, the transmitter 200 and the receiver 250 are implemented with a direct-conversion architecture.

In the transmit path, the baseband processor 102 (see FIG. 1B) provides data to a digital-to-analog converter (DAC) 202. The DAC 202 converts a digital input signal to an analog output signal. The analog output signal is provided to a filter 204, which filters the analog output signal to remove images caused by the prior digital-to-analog conversion by the DAC 202. An amplifier 206 is used to amplify the signal from the filter 204 to provide an amplified baseband signal. A mixer 208 receives the amplified baseband signal and an LO signal from TX local oscillator 210. The mixer 208 mixes the amplified baseband signal with the LO signal to provide an upconverted signal. A filter 212 is used to filter the upconverted signal to remove images caused by the frequency mixing. A power amplifier (PA) 214 is used to amplify the signal from the filter 212 to obtain an output RF signal at the desired output power level. The output RF signal is routed through a duplexer 260 to the antenna 106 for transmission over the wireless channel.

In the receive path, the antenna 106 may receive signals transmitted by a remote device. The received RF signal may be routed through the duplexer 260 to the receiver 250. Within the receiver 250, the received RF signal is amplified by a low noise amplifier (LNA) 252 and filtered by a filter 254 and to obtain an input RF signal. A mixer 256 receive the input RF signal and an LO signal from a RX local oscillator 258. The mixer 256 mixes the input RF signal with the LO signal to provide a downconverted signal. The downconverted signal is amplified by an amplifier 261 to obtain an amplified downconverted signal. A filter 262 is used to filter the amplified downconverted signal to remove images caused by the frequency mixing. The signal from the filter 262 is provided to an analog-to-digital converter (ADC) 264. The ADC 264 converts the signal to a digital output signal. The digital output signal may be provided to the baseband processor 102 (see FIG. 1B).

The conditioning of the signals in the transmitter 200 and the receiver 250 may be performed by one or more stages of amplifiers, filters, mixers, etc. These circuits may be arranged differently from the configuration shown in FIG. 2. Furthermore, other circuits not shown in FIG. 2 may also be used to condition the signals in the transmitter 200 and the receiver 250. For example, impedance matching circuits may be located at the output of the PA 216, at the input of the LNA 252, between the antenna 106 and the duplexer 260, etc.

Various embodiments of PLLs may be used to support transmitter and receiver functions. In one exemplary embodiment, the PLLs may be implemented with a VCO that provides the oscillating signal to the transmitter and/or receiver. An example of a VCO is a positive feedback amplifier that has a tuned resonator in the feedback loop. Oscillations occur at the resonant frequency, which can be tuned by the PLL. The PLL may be implemented with a phase detector that compares the phase of the VCO output with the phase of a reference signal and tunes the resonator of the VCO to keep the phases aligned.

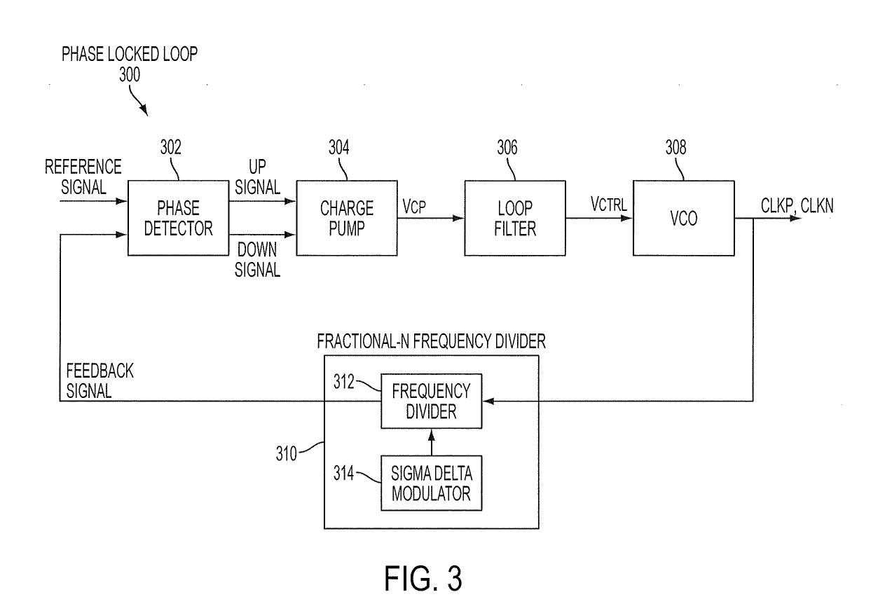

FIG. 3 is a block diagram illustrating an exemplary embodiment of a PLL. In this embodiment, the PLL 300 includes a phase detector 302, a charge pump 304, a loop filter 306, a VCO 308, and a fractional-N frequency divider 310 having a frequency divider 312 and a sigma delta modulator 314. The phase detector 302 provides a means for detecting a phase difference between two input signals. It is used to detect a phase error between a reference signal and a feedback signal from the fractional-N frequency divider 310. The phase detector 302 generates UP and DOWN signals based on the phase error. The UP and DOWN signals are used to drive the charge pump 304. The charge pump 304 provides a means for providing a current source to the loop filter 306. It injects a charge proportional to the detected phase error into the loop filter 306. The loop filter 306 provides a means for generating a control voltage (e.g., V_{CTRL}) for tuning the VCO 308. It integrates the output from the charge pump 304 to generate a control voltage that is input to the VCO 308. The VCO 308 provides a means for generating an oscillating signal having a tunable frequency. It generates an oscillating signal whose frequency is proportional to the control voltage (e.g., V_{CTRL}) generated by the loop filter 306. In the illustrated embodiment, the VCO 308 generates the differential oscillating signals CLKP and CLKN. The fractional-N frequency divider 310 provides a means for generating the feedback signal by fractionally dividing the frequency of the oscillating signals CLKP and CLKN. It includes the frequency divider 312 which divides the frequency of the VCO output by an integer N to produce the feedback signal input to the phase detector. It also includes the sigma delta modulator 314 that dynamically switches the value of N during the locked state to realize an average divider which is a non-integer between N and N+1.

The phase detector 302 compares the reference signal to the feedback signal from the fractional-N frequency divider 310 and activates the charge pump 304 based on the phase difference between the two signals. The phase detector 302 operates in a phase detection mode and a phase locked state. For this reason, the phase detector is sometimes referred to as a phase/frequency detector (PFD). For the purposes of this disclosure, the term “phase detector” shall be construed broadly to include a component capable of detecting a difference in phase and/or frequency of two input signals.

The phase detector 302 operates in a phase detection mode, in which the duty cycles of the UP and DOWN signals are varied based on the phase error measured by the phase detector 302. As a result, the charge pump 304 is activated for only a portion of the time, which is proportional to the phase difference between the two signals. The loop filter 306 accumulates a charge that produces a filtered control voltage (e.g., V_{CTRL}) which adjusts the frequency of the VCO output signal until the phase difference reaches zero. Once this occurs, the phase detector 302 enters the phase locked state. In this state, the duty cycles of the UP and DOWN signals are substantially equal, and therefore, no net charge is injected into the loop filter 306. The control voltage input to the VCO 308 remains constant, which ensures that the VCO output signal remains at a constant frequency. The loop filter 306 may be active or passive, and the charge pump 304 may also be implemented in several ways. These circuit elements may be implemented in accordance with the knowledge in the art.

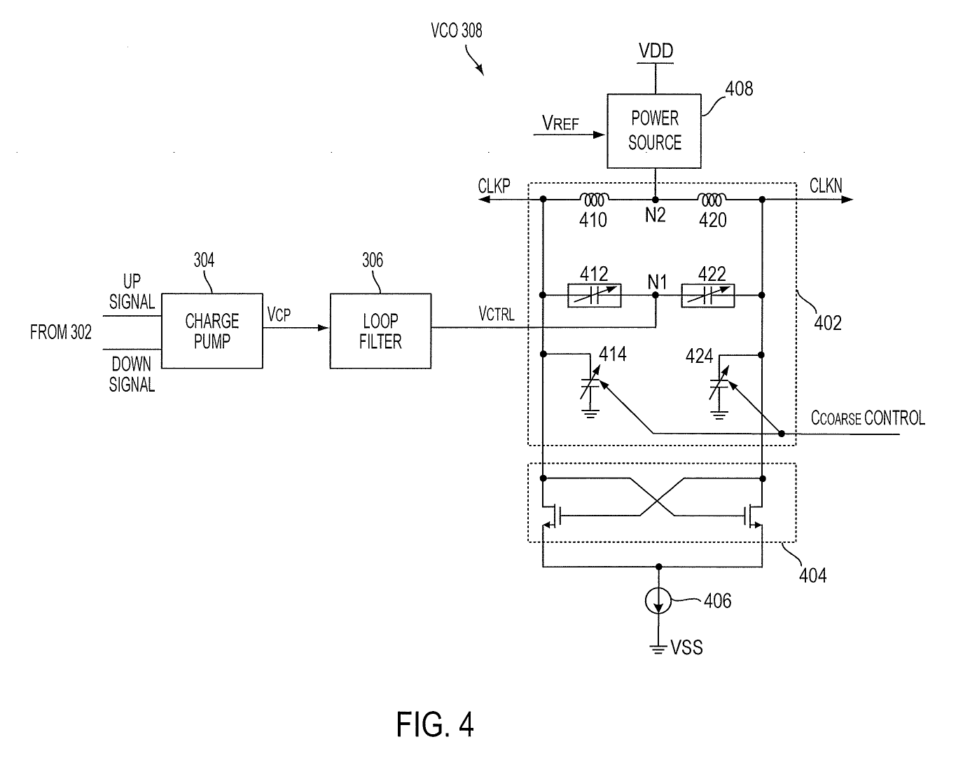

FIG. 4 is a block diagram illustrating an exemplary embodiment of a VCO including a voltage-controlled capacitive element. The VCO 308 includes a cross-coupled transistor pair 404, which operates as the gain stage of the VCO 308. In one example, the cross-coupled transistor pair 404 includes two N-type metal-oxide-semiconductor (MOS) transistors. The sources of the NMOS transistors are connected to a pull-down source 406, the capacity of which determines a swing of the outputs CLKP and CLKN. The pull-down source 406 discharges to a reference voltage VSS, such as ground. In one implementation, the pull-down source 406 includes a pull-down transistor. The VCO 308 further includes a power source 408 (e.g., a current source), which may be controlled by a voltage V_{REF}. The power source 408 is connected to a reference voltage VDD and controls the power supply (e.g., current flow) from VDD to the LC tank 402. In one implementation, the power source 408 provides the common mode voltage to the varactors 412 and 422 (described below).

The VCO 308 receives the control voltage V_{CTRL} and adjusts the oscillating frequency of the differential outputs CLKP and CLKN accordingly. The frequency adjustment results from adjusting the inductance-capacitance (LC) constant of the LC tank 402. In one example, the LC constant of the LC tank 402 is adjusted based on the voltage level of the control voltage V_{CTRL}. The LC tank 402 includes inductors 410 and 420, which account for the inductance portion of the LC constant. The inductors 410 and 420 are connected to the power source 408 at node N2. The inductor 410 is connected to the output CLKP, and the inductor 420 is connected to the CLKN. The capacitors of the LC tank 402 include tunable capacitors 414 and 424. The tunable capacitor 414 is connected to the output CLKP, and the tunable capacitor 424 is connected to the output CLKN. In one example, the tunable capacitors 414 and 424 may be capacitor banks selected by C_{COARSE} CONTROL signals. A capacitor bank may include a plurality of capacitors selectively connected by the control signals, as is known in the art. In one implementation, the tunable capacitors 414 and 424 are tuned for coarse capacitance adjustments (as compared to the adjustments of the varactors 412 and 422).

The LC tank 402 includes voltage-controlled capacitive elements, such as the varactors 412 and 422. The varactors 412 and 422 receive the control voltage V_{CTRL} at node N1. The varactor 412 is connected to the output CLKP, and the varactor 422 is connected to the output CLKN. An example of a varactor includes a diode with a variable depletion region. The input voltage voltage-controlled capacitive element varies the depletion region and therefore, the capacitance of the device. In one implementation, the varactors 412 and 422 are tuned by the control the voltage V_{CTRL} at node N1 for fine capacitance adjustments (as compared to the adjustments by the changing the selections on the tunable capacitors 414 and 424). The varactors 412 and 422 operate with the inductors 410, 420 and the tunable capacitors 414 and 424 to output the CLKP and CLKN at a given frequency.

Various embodiments of methods and apparatus for PLLs and VCOs to calibrate the varactors are provided. The PLLs and VCOs may calibrate and adjust the bias points for the varactors to compensate for process and technology change. Moreover, the responses of the varactors are not static; the responses may be operational frequency dependent. In one example, since the tunable capacitors 414 and 424 are tuned for coarser capacitance adjustments by the C_{COARSE} CONTROL signals, the responses of the varactors (and therefore the oscillating frequency of the VCO 308) may depend on the settings of the C_{COARSE} CONTROL signals.

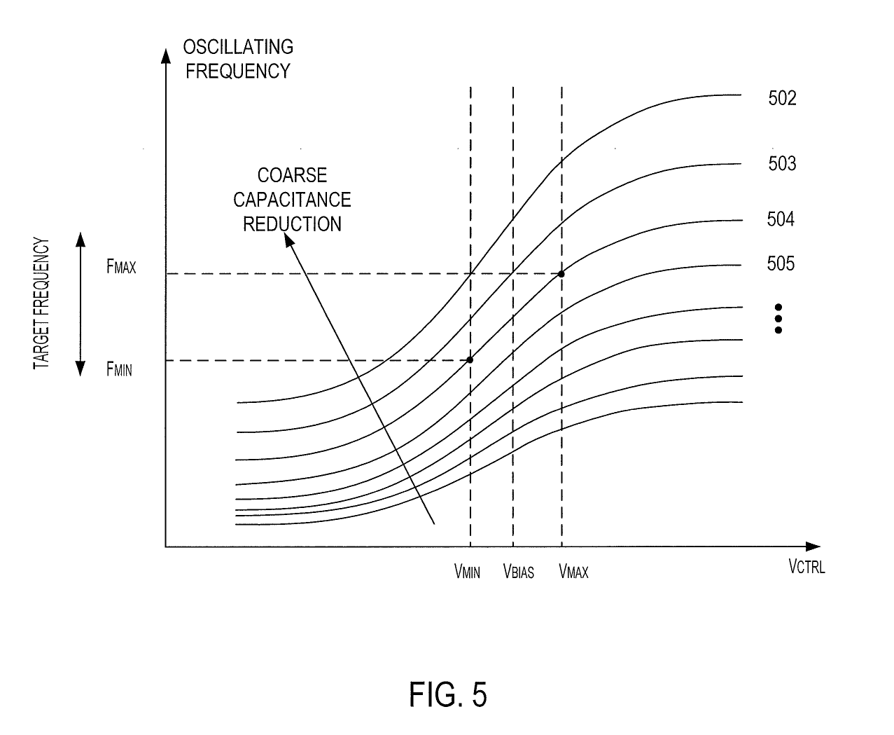

FIG. 5 is a graph illustrating the oscillating frequency of a VCO in response to the operational frequency and the control voltage. FIG. 5 illustrates the control voltage V_{CTRL} on the X-axis, and the oscillating frequency of the VCO 308 on the Y-axis. In one implementation, each response curve is for a particular setting of the tunable capacitors 414 and 424. As described above, the tunable capacitors 414 and 424 are tuned for coarse capacitance adjustments by the C_{COARSE} CONTROL signals. The oscillating frequency response of the VCO 308 may depend on the set coarse capacitance (therefore, an operation frequency). In one implementation, the oscillating frequency of the VCO 308 may be adjusted by the capacitances of the varactors 412 and 422 (when the coarse capacitances are set). As described above, the control voltage V_{CTRL} controls the capacitance of the varactors 412 and 422, upon which the oscillating frequency of the VCO (outputs CLKP and CLKN) is based.

FIG. 5 illustrates the various responses of the oscillating frequency of the VCO 308 based on the coarse capacitances (e.g., provided by the tunable capacitors 414 and 424). Each response curve (e.g., 502) may correspond to a gain response of the VCO, K_{VCO}, for a particular selected capacitance of the tunable capacitors 414 and 424. K_{VCO} may represent changes of the oscillating frequency (Δf) vs. changes of the control voltage V_{CTRL} (Δv). The responses are not uniform in term of, e.g., the slopes. For example, the response curves are not in parallel. For example, if the response 504 is selected (by a setting of the C_{COARSE} CONTROL signals), the setting of the bias voltage V_{BIAS} of the varactors 412 and 422 may determine a range (F_{MIN}-F_{MAX}) of the oscillating frequency of the VCO 308. In one example, the bias voltage V_{BIAS} is a voltage at the center of the operation voltage range which allows for a maximum frequency swing of the control voltage V_{CTRL}. In one example, the bias voltage V_{BIAS} of the varactors 412 and 422 may be a voltage across the nodes N1 and N2. A target frequency may be within the range F_{MIN}-F_{MAX}. In one implementation, the charge pump 304 may provide a limited range of the control voltage V_{CTRL} (V_{MIN}-V_{MAX}) centered around the bias voltage V_{BIAS}. Such range may be limited by practical concerns such as the response time and the response granularity of the charge pump 304. Thus, one aspect of PLL and VCO calibration is to maximize the oscillating frequency response (e.g., maximize changes of the oscillating frequency (Δf) vs. changes of the control voltage V_{CTRL} (Δv)).

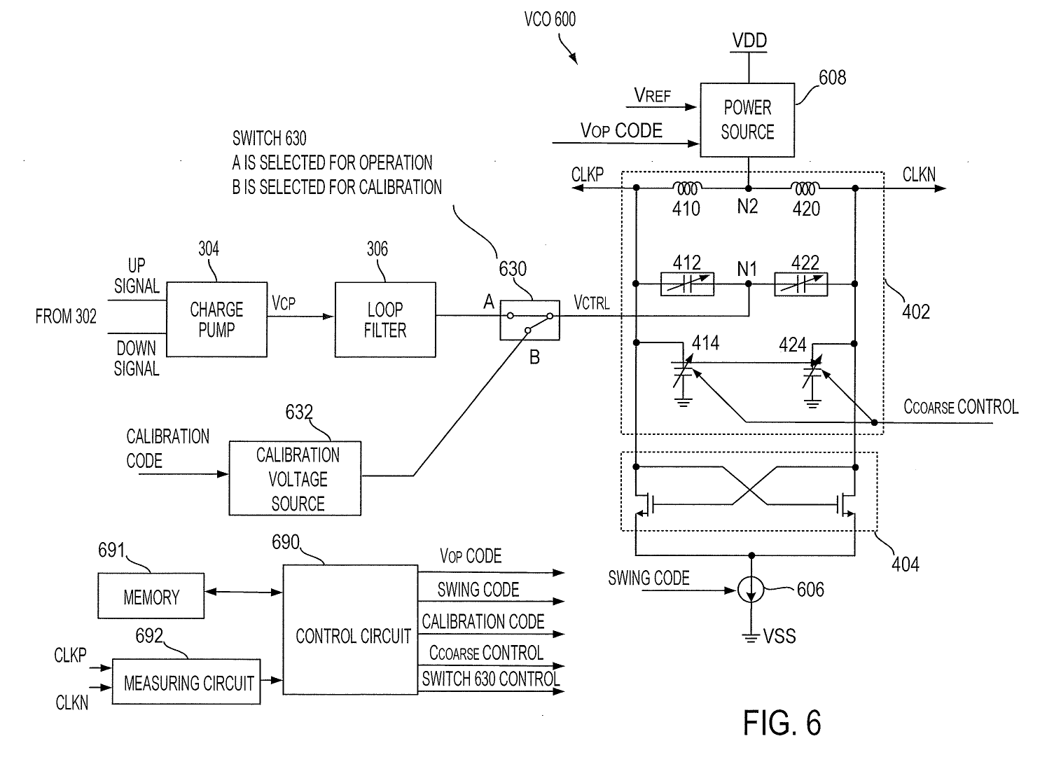

FIG. 6 is a block diagram illustrating an exemplary embodiment of a VCO with varactor calibration. The VCO 600 includes a calibration voltage source 632, which may be selectively connected to provide the control voltage V_{CTRL} during a calibration mode. In one implementation, the calibration voltage source 632 may be implemented using a voltage divider (e.g., resistors connected in series between a power source and ground) and digitally controlled by the CALIBRATION CODE signals to provide a range of voltages to the control voltage V_{CTRL} in the calibration mode. A switch 630 may control the connection to the control voltage V_{CTRL}. In the calibration mode, the switch 630 connects the calibration voltage source 632 to the control voltage V_{CTRL} (setting B). In an operation mode, the switch 630 connects the charge pump 304 and the loop filter 306 to the control voltage V_{CTRL} (setting A), as described with FIG. 4.

The VCO 600 further includes a programmable pull-down source 606, the pull-down capacity of which may be controlled by digital SWING CODE signals. The VCO 600 further includes a programmable power source 608, the capacity of which may be controlled by digital V_{OP} CODE signals. In the operation mode, the loop filter 306 is connected to the control voltage V_{CTRL} input at the node N1. The power source 608 is connected to the common voltage node N2. In one implementation, the operation voltage of the varactors 412 and 422 may be provided by the power source 608 (with respect to the voltage provided by the charge pump 304). In this fashion, the calibration of the VCO 600 is isolated from the charge pump 304 and loop filter 306. In one implementation, the charge pump 304 and the loop filter 306 are not used in the calibration mode, and do not need to be configured to provide the operation voltage of the varactors 412 and 422 determined in the calibration mode. In one implementation, the selection of the operation voltage (such as the bias voltage V_{BIAS}) for the varactors 412 and 422 needs not alter a configuration of the charge pump 304 and the loop filter 306.

A memory 691 is provided to store a result of calibrating the VCO 600. The memory may be implemented with a register, a non-volatile memory, or other types of memories known in the art. In one example, the memory 691 is configured to store frequency information indicating frequencies of the outputs CLKP and CLN generated in response to the plurality of voltages provided to the varactors 412 and 422.

A control circuit 690 may be configured to control the various features of the VCO 600 presented above. The control circuit 690 may be implemented in hardware/circuit, software, or combination thereof in accordance with the knowledge of persons of ordinary skill in the art. For example, the modules may include logic gates to perform the functions described herein, processor(s) performing those functions, logic gates generating the signals for the functions described herein, or combinations thereof. In one example, the control circuit 690 may refer to the logic gates generating the CALIBRATION CODE signals, the V_{OP} CODE signals, the C_{COARSE} CONTROL signals, and the SWING CODE signals. The control circuit 690 may further be configured to provide the switch 630 control signal that controls the settings (A or B) of the switch 630.

An example of the operations of the VCO 600 and a PLL incorporating the VCO 600 are presented below. The VCO 600 may be calibrated in a calibration mode to generate the frequency information. In the calibration mode, the PLL incorporating the VCO 600 may be placed in an open loop configuration. For example, the PLL 300 may incorporate the VCO 600, which includes varactors 412 and 422. The PLL 300 may be placed in an open loop configuration when the feedback signal is disconnected or disabled from the phase detector 302.

In the calibration mode, the control circuit 690 may be configured to set each of the tunable capacitors 414 and 424 to a plurality of capacitances by varying the C_{COARSE} CONTROL signals. For each of the capacitance settings of the tunable capacitors 414 and 424, the control circuit 690 may be configured to provide a plurality of voltages from the calibration voltage source 632 to the varactors 412 and 422.

Examples of providing the plurality of voltages from the calibration voltage source 632 to the varactors 412 and 422 are presented below. The control circuit 690 may be configured to switch the switch 630 from the setting A to the Setting B, thereby disconnecting the charge pump 304 and the loop filter 306 to the varactors 412 and 422. This step may also place the PLL incorporating the VCO 600 in the open loop configuration, as the feedback to the VCO 600 is disconnected. With the switch 630 at setting B, the calibration voltage source 632 is connected to the varactors 412 and 422. For each of the capacitance settings of the tunable capacitors 414 and 424, the control circuit may be configured to provide a plurality of voltages to the varactors 412 and 422 by arranging the power source 608 to output a reference voltage to the node N2. This step may be implemented by using the V_{OP} CODE signals. In this fashion, the plurality of voltages may be provided to the varactors 412 and 422 via the node N1 with the node N2 serving as a reference.

With the node N2 set to the reference voltage (e.g., ground), for each capacitance setting of the tunable capacitors 414 and 424, the control circuit 690 may provide the plurality of voltage to the varactors 412 and 422 (e.g., providing the voltages to the node N1) by varying the CALIBRATION CODE signals. The VCO 600 outputs CLKP and CLKN oscillate in varying frequencies in response to the plurality of voltages provided to the varactors 412 and 422. A measuring circuit 692 measures the frequencies of the outputs CLKP and CLKN generated in response to the plurality of voltages provided to the varactors 412 and 422 and provides the frequency information to a control circuit 690. The control circuit 690 may be configured to store in the memory 619 the frequency information indicating the frequencies of the output nodes CLKP and CLKN generated in response to the plurality of voltages provided to the varactors 412 and 422.

In one configuration, the stored frequency information may reflect the graph of FIG. 5. The frequency information may be stored in the memory 619 to include the generated frequencies (the y-axis) with respect to the provided voltages (the x-axis). Moreover, the frequency information may be stored with respect to each capacitance setting of the tunable capacitors 414 and 424 (e.g., each of the responses 502, 503, 504, etc. represents each capacitance setting).

In another aspect of the VCO 600, the control circuit 690 may be configured to maximize an amplitude swing of the outputs CLKP and CLKN. In one example, the control circuit 690 may be configured to generate the SWING CODE signals corresponding to the maximum amplitude swing for the outputs CLKP and CLKN for each of the plurality of voltages provided to the varactors 412 and 422. In the calibration mode, for each of the plurality of voltages provided to the varactors 412 and 422, the control circuit 690 may sweep the SWING CODE signals to obtain a set of the SWING CODE signals that produces the maximum amplitude swing for the outputs CLKP and CLKN. The frequency information stored in the memory 691 may store the set of the SWING CODE signals that produces the maximum amplitude swing with respect to each of the plurality of voltages provided to the varactors 412 and 422.

In the calibration mode (e.g., the PLL incorporating the VCO 600 is in the open loop configuration), the control circuit 690 may set the calibration voltage source 632 to output a reference voltage (e.g., ground) to node N1 of the varactors 412 and 422. The control circuit 690 may sweep the V_{OP} CODE signals and generate, as a response, CLKP and CLKN oscillating at various frequencies. This set of frequencies and V_{OP} CODE signals relationship may be stored in the in the memory 691 as part of the frequency information.

The control circuit 690 may be configured to select the operation voltage for the varactors 412 and 422 based on the stored frequency information using various factors. In one example, the operation voltage may be selected for a maximum frequency swing produced by a change in the operation voltage of the varactors 412 and 422. For example, if the response 504 is selected (by a setting of the C_{COARSE} CONTROL signals), the setting of the bias voltage V_{BIAS} of the varactors 412 and 422 may determine a range (F_{MIN}-F_{MAX}) of the oscillating frequency of the VCO 308. In one example, the bias voltage V_{BIAS} is a voltage at the center of the operation voltage range which allows for a maximum frequency swing of the output signal. Thus, the operation voltage for the varactors 412 and 422 may be selected to maximize a change in the frequencies of the output signal (e.g., outputs CLKP and CLKN) in response to a change in voltages of the varactors 412 and 422 (e.g., across the nodes N1 and N2). In one example, referring to FIG. 5, a capacitance setting of the tunable capacitors 414 and 424 may be selected based on a target frequency and the frequency information stored in the memory 691. Moreover, the operation voltage for the varactors 412 and 422 may be selected based on the target frequency and the frequency information stored in the memory 691. The target frequency may be within the range F_{MIN}-F_{MAX} outputted by the selected capacitance setting of the tunable capacitors 414 and the selected operation voltage for the varactors 412 and 422. In one example, the selected operation voltage for the varactors 412 and 422 may be the bias voltage V_{BIAS}, which is a voltage at the center of the operation voltage range (V_{MIN}-V_{MAX}) which allows for a maximum frequency swing of the output signals CLKP and CLKN.

As shown in FIG. 5, a gain of the VCO 600, K_{VCO}, may depend on the operation frequency and therefore, the selected capacitance of the tunable capacitors 414 and 424 (selecting the responses 502, 503, 504, etc.). The selection of the operation voltage of the varactors 412 or 422 based on the selected capacitance of the tunable capacitors 414 and 424 accounts for operation frequency. The VCO 600 may accordingly be calibrated accurately with regard to the temperature and process variations. For example, the selection of the operation voltage of the varactors 412 or 422 may be to maximize the K_{VCO} of the VCO 600. In one example, a K_{VCO} peak finder circuit may be utilized for the selection.

In an operation mode (e.g., the PLL incorporating the VCO 600 is in a closed loop configuration), the selected operation voltage (e.g., V_{BIAS}) may be provided to the varactors 412 and 422 by, e.g., the power source 608. To facilitate this feature, the control circuit 690 may be configured to generate the needed V_{OP} CODE signal to instruct the power source 608 to provide the selected operation voltage. For example, as described above, the memory 691 may include the set of frequencies and V_{OP} CODE signals relationship. The V_{OP} CODE signal may be selected therefrom that matches best with the selected the operation voltage. For example, the V_{OP} CODE signals-to-output frequencies relationship best matches the selected operation voltage and the associated frequency responses may be selected. The control circuit 690 may be configured to provide the selected operation voltage to the varactors 412 and 422 (at node N2) by providing the corresponding V_{OP} CODE signals to the power source 608. In this fashion, the selected operation voltage may be provided as V_{BIAS} to varactors 412 and 422 at node N2 by the power source 608.

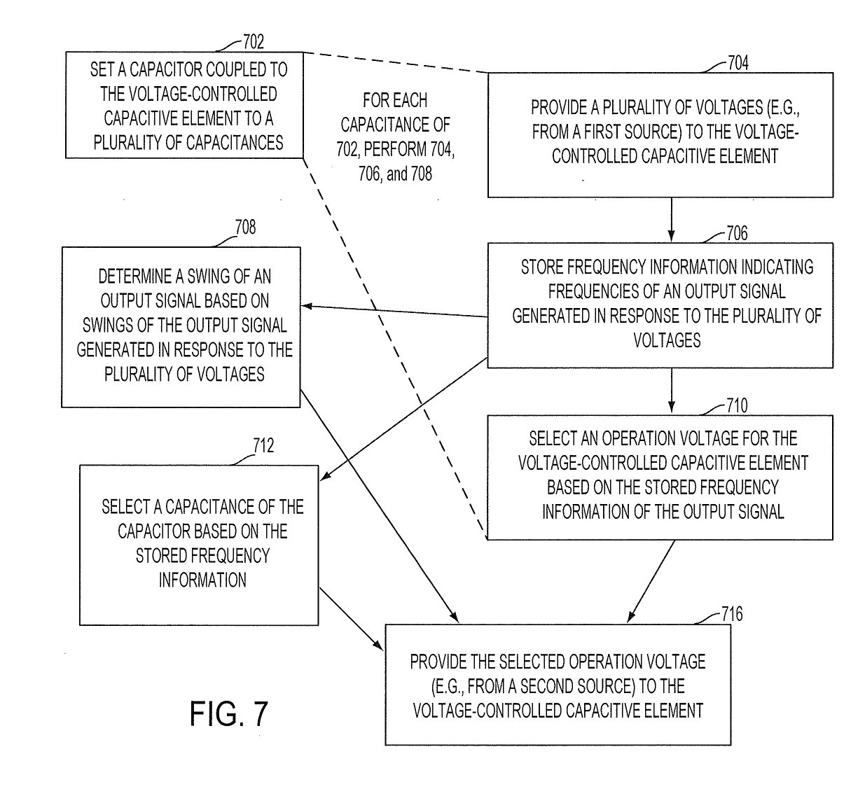

FIG. 7 is a flow chart for calibrating a PLL and a VCO. In one implementation, 702, 704, 706, and 708 may be part of a calibration mode. In one implementation, 702, 704, 706, and 708 may be performed by a PLL in an open loop configuration. In one implementation, 716 may be part of an operation mode. In one implementation, 716 may be performed by the PLL in a closed loop configuration.

At 702, a capacitor coupled to the voltage-controlled capacitive element is set to a plurality of capacitances in the open loop configuration. For example, the PLL 300 may incorporate the VCO 600, which includes varactors 412 and 422. The PLL 300 may be placed in an open loop configuration when the feedback signal is disconnected or disabled from the phase detector 302. In the calibration mode, the control circuit 690 may be configured to set the set each of the tunable capacitors 414 and 424 to a plurality of capacitances by varying the C_{COARSE} CONTROL signals. For each of the capacitance settings of the tunable capacitors 414 and 424, the control circuit 690 may be configured to provide a plurality of voltages from the calibration voltage source 632 to the varactors 412 and 422.

In one implementation, steps 704, 706, and 708 may be performed for each of the capacitance of step 702. At 704, a plurality of voltages is provided (e.g., from a first source) to the voltage-controlled capacitive element. For example, the control circuit 690 may be configured to switch the switch 630 from the setting A to the Setting B, thereby disconnecting the charge pump 304 and the loop filter 306 to the varactors 412 and 422. This step may also place the PLL incorporating the VCO 600 in the open loop configuration, as the feedback to the VCO 600 is disconnected. With the switch 630 at setting B, the calibration voltage source 632 is connected to the varactors 412 and 422. For each of the capacitance settings of the tunable capacitors 414 and 424, the control circuit may be configured to provide a plurality of voltages to the varactors 412 and 422 by arranging the power source 608 to output a reference voltage (e.g., ground) to the node N2. This step may be implemented by using the V_{OP} CODE signals. In this fashion, the plurality of voltages may be provided to the varactors 412 and 422 via the node N1 with the node N2 serving as a reference.

With the node N2 set to the reference voltage (e.g., ground), for each capacitance setting of the tunable capacitors 414 and 424, the control circuit 690 may provide the plurality of voltage to the varactors 412 and 422 (e.g., providing the voltages to the node N1) by varying the CALIBRATION CODE signals. The VCO 600 outputs CLKP and CLKN oscillate in varying frequencies in response to the plurality of voltage provided to the varactors 412 and 422.

At 706, frequency information indicating frequencies of an output signal generated in response to the plurality of voltages is stored. For example, the control circuit 690 may be configured to store in the memory 619 the frequency information indicating the frequencies of the output nodes CLKP and CLKN generated in response to the plurality of voltages provided to the varactors 412 and 422. In one configuration, the stored frequency information may reflect the graph of FIG. 5. The frequency information may be stored in the memory 619 to include the generated frequencies (the y-axis) with respect to the provided voltages (the x-axis). Moreover, the frequency information may be stored with respect to each capacitance setting of the tunable capacitors 414 and 424 (e.g., each of the responses 502, 503, 504, etc. represents each capacitance setting).

At 708, a swing of the output signal is determined based on swings of the output signal generated in response to the plurality of voltages. For example, the control circuit 690 may be configured to maximize an amplitude swing of the outputs CLKP and CLKN. In one example, the control circuit 690 may be configured to generate the SWING CODE signals corresponding to the maximum amplitude swing for the outputs CLKP and CLKN for each of the plurality of voltages provided to the varactors 412 and 422. In the calibration mode, for each of the plurality of voltages provided to the varactors 412 and 422, the control circuit 690 may sweep the SWING CODE signals to obtain a set of the SWING CODE signals that produces the maximum amplitude swing for the outputs CLKP and CLKN. The frequency information stored in the memory 691 may store the set of the SWING CODE signals that produces the maximum amplitude swing with respect to each of the plurality of voltages provided to the varactors 412 and 422.

At 710, an operation voltage for the voltage-controlled capacitive element is selected based on the stored frequency information of the output signal. For example, the control circuit 690 may be configured to select a bias voltage V_{BIAS} for the varactors 412 and 422 and for the operation mode. In one implementation, the control circuit 690 may select the bias voltage V_{BIAS} based on the maximizing changes of the oscillating frequency (Δf) vs. changes of the control voltage V_{CTRL} (Δv)(e.g., maximize K_{VCO}).

In one example, the operation voltage may be selected for a maximum frequency swing produced by a change in the operation voltage of the varactors 412 and 422. For example, if the response 504 is selected (by a setting of the C_{COARSE} CONTROL signals), the setting of the bias voltage V_{BIAS} of the varactors 412 and 422 may determine a range (F_{MIN}-F_{MAX}) of the oscillating frequency of the VCO 308. In one example, the bias voltage V_{BIAS} is a voltage at the center of the operation voltage range which allows for a maximum frequency swing of the output signal. Thus, the operation voltage for the varactors 412 and 422 may be selected to maximize a change in the frequencies of the output signal (e.g., outputs CLKP and CLKN) in response to a change in voltages of the varactors 412 and 422 (e.g., across the nodes N1 and N2). In one example, referring to FIG. 5, a capacitance setting of the tunable capacitors 414 and 424 may be selected based on a target frequency. Moreover, the operation voltage for the varactors 412 and 422 may be selected based on the target frequency and the frequency information stored in the memory 691. The target frequency may be within the range F_{MIN}-F_{MAX} outputted by the selected capacitance setting of the tunable capacitors 414 and the selected operation voltage for the varactors 412 and 422. In one example, the selected operation voltage for the varactors 412 and 422 may be the bias voltage V_{BIAS}, which is a voltage at the center of the operation voltage range (V_{MIN}-V_{MAX}) which allows for a maximum frequency swing of the output signals CLKP and CLKN.

At 712, a capacitance of the capacitor is selected based on the stored frequency information. For example, a capacitance setting of the tunable capacitors 414 and 424 may be selected based on a target frequency and the frequency information stored in the memory 691. Moreover, the operation voltage for the varactors 412 and 422 may be selected based on the target frequency and the frequency information stored in the memory 691. The target frequency may be within the range F_{MIN}-F_{MAX} outputted by the selected capacitance setting of the tunable capacitors 414 and the selected operation voltage for the varactors 412 and 422. In one example, the selected operation voltage for the varactors 412 and 422 may be the bias voltage V_{BIAS}, which is a voltage at the center of the operation voltage range (V_{MIN}-V_{MAX}) which allows for a maximum frequency swing of the output signals CLKP and CLKN.

At 716, the operation voltage is provided (e.g., from a second source) to the voltage-controlled capacitive element. For example, in an operation mode (e.g., the PLL incorporating the VCO 600 is in a closed loop configuration), the selected operation voltage may be provided to the varactors 412 and 422 by, e.g., the power source 608. As presented above, the frequency information stored in the memory 691 may include a setting of the power source (V_{OP} CODE signals) that corresponds to the selected operation voltage. The control circuit 690 may be configured to provide the selected operation voltage to varactors 412 and 422 (at node N2) by providing the corresponding V_{OP} CODE signals to the power source 608.

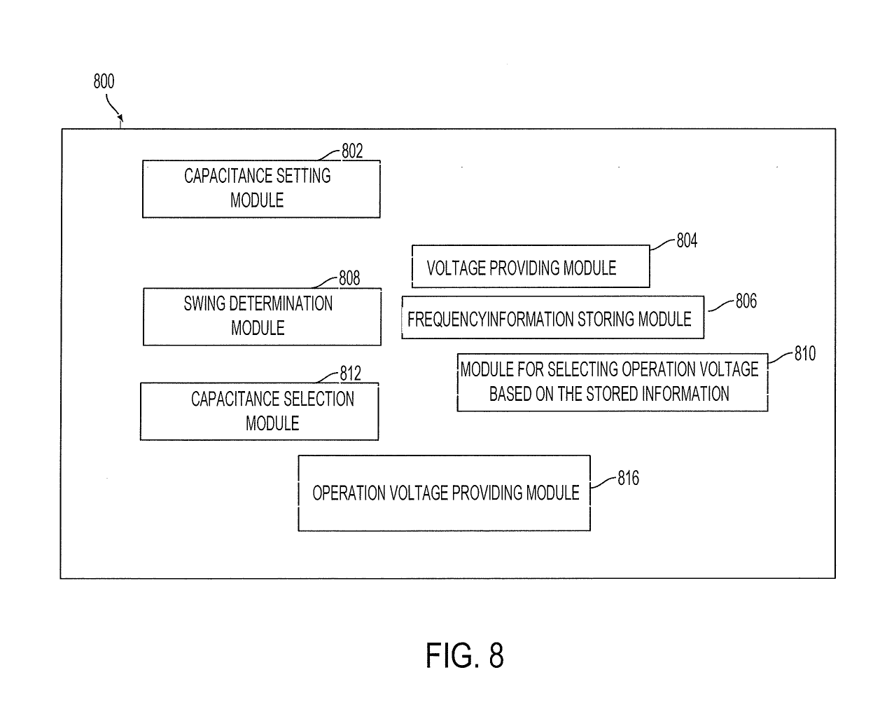

FIG. 8 is a functional block diagram illustrating an exemplary embodiment of control circuits of a PLL and a VCO with varactor calibration. The control circuit 800 may be an example of the control circuit 690. The control circuit 800 may include a capacitance setting module 802 for setting, in the open loop configuration, a capacitor coupled to the voltage-controlled capacitive element to a plurality of capacitances. Examples of the capacitance setting module 802 are presented with FIG. 6, such as the features relating to the control circuit 690 operating the C_{COARSE} CONTROL signals to set the capacitances of the tunable capacitors 414 and 424.

A voltage providing module 804 provides a plurality of voltages (e.g., from a first source) to a voltage-controlled capacitive element. Examples of the voltage providing module 804 are presented with FIG. 6, such as the features relating to the control circuit 690 operating the CALIBRATION CODE signals to range the calibration voltage source 632 to provide a plurality of voltages to the varactors 412 and 422 in a calibration mode.

A frequency information storing module 806 provides storing of frequency information indicating frequencies of an output signal generated in response to the plurality of voltages. Examples of the frequency information storing module 806 are presented with FIG. 6, such as the features relating to the control circuit 690 storing the frequencies of the outputs CLKP and CLKN generated in response to a plurality of voltages generated provided to the varactors 412 and 422 in the memory 691.

A swing determination module 808 provides for determining a swing of the output signal based on swings of the output signal generated in response to the plurality of voltages. Examples of the swing determination module 808 are presented with FIG. 6, such as the features relating to the control circuit 690 outputting the SWING CODE signals that generate the maximum amplitude swing on the outputs CLKP and CLKN for a given operation voltage of the varactors 412 and 422.

A module for selecting operation voltage selection based on the stored information 810 selects the operation voltage based on, e.g., the frequency information stored in the memory 691. Examples of the module for selecting operation voltage selection based on the stored information 810 are presented with FIG. 6, such as the features relating to the control circuit 690 selecting the operation voltage (e.g., V_{bias} of FIG. 5) based on the frequency information stored in the memory 691.

A capacitance selection module 812 selects, in the closed loop configuration, a capacitance of the capacitor based on the stored frequency information. Examples of the capacitance selection module 812 are presented with FIGS. 5 and 6, such as the features relating to the control circuit 690 selecting a capacitance of the tunable capacitors 414 and 424 (corresponding to a response of FIG. 5) based on the frequency information stored in the memory 691.

An operation voltage providing module 816 provides the selected operation voltage (e.g., from a second source) to the voltage-controlled capacitive element. Examples of the operation voltage providing module 816 are presented with FIG. 6, such as the features relating to the control circuit 690 generating the V_{OP} CODE signals to arrange the power source 608 to provide the selected operation voltage to the node N2.

The modules may be one or more hardware components specifically configured to carry out the stated processes/algorithm, implemented by a processor configured to perform the stated processes/algorithm, stored within a computer-readable medium for implementation by a processor, or some combination thereof.

The control circuit 800 may include additional modules that perform each of the steps of the algorithm in the aforementioned flow chart of FIG. 7. As such, each step in the aforementioned flow chart of FIG. 7 may be performed by a module and the apparatus may include one or more of those modules. In an example, the control circuit 800 may include means for providing, in an open loop configuration, a plurality of voltages to a voltage-controlled capacitive element. The control circuit 800 may further include means for storing, in the open loop configuration, frequency information indicating frequencies of an output signal generated in response to the plurality of voltages being provided to the voltage-controlled capacitive element and means for providing, in a closed loop configuration, a selected operation voltage to the voltage-controlled capacitive element, wherein the selected operation voltage is selected based on the stored frequency information. The control circuit 800 may further include means for determining a swing of the output signal based on swings of the output signal generated in response to the plurality of voltages. The control circuit 800 may further include means for setting, in the open loop configuration, a capacitor coupled to the voltage-controlled capacitive element to a plurality of capacitances. The control circuit 800 may further include means for selecting, in the closed loop configuration, a capacitance of the capacitor based on the stored frequency information.

The specific order or hierarchy of blocks in the method of operation described above is provided merely as an example. Based upon design preferences, the specific order or hierarchy of blocks in the method of operation may be re-arranged, amended, and/or modified. The accompanying method claims include various limitations related to a method of operation, but the recited limitations are not meant to be limited in any way by the specific order or hierarchy unless expressly stated in the claims.

The previous description is provided to enable any person skilled in the art to fully understand the full scope of the disclosure. Modifications to the various exemplary embodiments disclosed herein will be readily apparent to those skilled in the art. Thus, the claims should not be limited to the various aspects of the disclosure described herein, but shall be accorded the full scope consistent with the language of claims. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f) unless the element is expressly recited using the phrase “means for” or, in the case of a method claim, the element is recited using the phrase “step for.”

What is claimed is:

1. A method for operating a voltage-controlled oscillator, comprising:
providing a plurality of voltages from a first source to a voltage-controlled capacitive element;
storing frequency information indicating frequencies of an output signal generated in response to the plurality of voltages;
selecting an operation voltage for the voltage-controlled capacitive element based on the stored frequency information of the output signal; and
providing the operation voltage from a second source to the voltage-controlled capacitive element.

2. The method of claim 1, wherein the voltage-controlled capacitive element comprises a varactor capacitor.

3. The method of claim 1, wherein the plurality of voltages is provided to a first node of the voltage-controlled capacitive element, and the operation voltage is provided to a second node of the voltage-controlled capacitive element.

4. The method of claim 1, wherein the selecting the operation voltage for the voltage-controlled capacitive element is based on a target frequency.

5. The method of claim 4, wherein the selecting the operation voltage for the voltage-controlled capacitive element is further based a change in the frequencies of the output signal in response to a change in voltages of the voltage-controlled capacitive element.

6. The method of claim 1, further comprising determining a swing of the output signal based on swings of the output signal generated in response to the plurality of voltages.

7. A method for operating a phase-locked loop, comprising:
providing, in an open loop configuration, a plurality of voltages to a voltage-controlled capacitive element;
storing, in the open loop configuration, frequency information indicating frequencies of an output signal generated in response to the plurality of voltages;
providing, in a closed loop configuration, a selected operation voltage to the voltage-controlled capacitive element, wherein the selected operation voltage is selected based on the stored frequency information.

8. The method of claim 7, wherein the plurality of voltages is provided to the voltage-controlled capacitive element from a first source; and the selected operation voltage is provided to the voltage-controlled capacitive element from a second source.

9. The method of claim 7, wherein the voltage-controlled capacitive element comprises a varactor capacitor.

10. The method of claim 7, wherein the plurality of voltages is provided to a first node of the voltage-controlled capacitive element, and the selected operation voltage is provided to a second node of the voltage-controlled capacitive element.

11. The method of claim 7, wherein the selected operation voltage is selected further based a change in the frequencies of the output signal in response to a change in voltages of the voltage-controlled capacitive element.

12. The method of claim 7, further comprising determining a swing of the output signal based on swings of the output signal generated in response to the plurality of voltages.

13. The method of claim 7, further comprising setting, in the open loop configuration, a capacitor coupled to the voltage-controlled capacitive element to a plurality of capacitances.

14. The method of claim 13, wherein the plurality of voltages is provided to the voltage-controlled capacitive element for each of the plurality of capacitances of the capacitor, and the frequency information is stored for each of the plurality of capacitances of the capacitor.

15. The method of claim 14, further comprising selecting, in the closed loop configuration, a capacitance of the capacitor based on the stored frequency information.

16. A voltage-controlled oscillator apparatus, comprising:
an inductor;
a voltage-controlled capacitive element configured to operate with the inductor to generate an oscillating signal;
a voltage supply configured to provide a plurality of voltages to the voltage-controlled capacitive element in a calibration mode; and
a control circuit configured to store frequency information indicating frequencies of the oscillating signal in response to the plurality of voltages being provided to the voltage-controlled capacitive element.

17. The voltage-controlled oscillator apparatus of claim 16, wherein the control circuit is further configured to select an operation voltage for the voltage-controlled capacitive element based on the stored frequency information indicating the frequencies of the oscillating signal.

18. The voltage-controlled oscillator apparatus of claim 17, wherein the control circuit is configured to select the operation voltage for the voltage-controlled capacitive element based on a target frequency.

19. The voltage-controlled oscillator apparatus of claim 18, wherein the control circuit is configured to select the operation voltage for the voltage-controlled capacitive element based on a change in the frequencies of the oscillating signal in response to a change in voltages of the voltage-controlled capacitive element.

20. The voltage-controlled oscillator apparatus of claim 17, further comprising a second voltage supply configured to supply a voltage to the voltage-controlled capacitive element based on the operation voltage in an operation mode.

21. The voltage-controlled oscillator apparatus of claim 20, wherein the voltage-controlled capacitive element comprises a first node and a second node, and wherein the voltage supply is configured to provide the first node in the calibration mode, and the second voltage supply configured to supply the voltage to the second node based on the operation voltage in the operation mode.

22. A phase-locked loop apparatus, comprising:
means for providing, in an open loop configuration, a plurality of voltages to a voltage-controlled capacitive element;
means for storing, in the open loop configuration, frequency information indicating frequencies of an output signal generated in response to the plurality of voltages being provided to the voltage-controlled capacitive element;
means for providing, in a closed loop configuration, a selected operation voltage to the voltage-controlled capacitive element, wherein the selected operation voltage is selected based on the stored frequency information.

23. The phase-locked loop apparatus of claim 22, wherein the means for providing the plurality of voltages to the voltage-controlled capacitive element comprise a first source to provide the plurality of voltages; and the means for providing the selected operation voltage to the voltage-controlled capacitive element comprises a second source to provide the selected operation voltage.

24. The phase-locked loop apparatus of claim 22 wherein the voltage-controlled capacitive element comprises a varactor capacitor.

25. The phase-locked loop apparatus of claim 22, wherein the means for providing the plurality of voltages to the voltage-controlled capacitive element is configured to provide the plurality of voltages to a first node of the voltage-controlled capacitive element, and the means for providing the selected operation voltage to the voltage-controlled capacitive element is configured to provide the selected operation voltage to a second node of the voltage-controlled capacitive element.

26. The phase-locked loop apparatus of claim 22, wherein the selected operation voltage is selected further based a change in the frequencies of the output signal in response to a change in voltages of the voltage-controlled capacitive element.

27. The phase-locked loop apparatus of claim 22, further comprising means for determining a swing of the output signal based on swings of the output signal generated in response to the plurality of voltages.

28. The phase-locked loop apparatus of claim 27, further comprising means for setting, in the open loop configuration, a capacitor coupled to the voltage-controlled capacitive element to a plurality of capacitances.

29. The phase-locked loop apparatus of claim 28, wherein the means for providing the plurality of voltages to the voltage-controlled capacitive element is configured to provide the voltage-controlled capacitive element for each of the plurality of capacitances of the capacitor.

30. The phase-locked loop apparatus of claim 29, further comprising means for selecting, in the closed loop configuration, a capacitance of the capacitor based on the stored frequency information.
